(19) United States
(12) Patent Application Publication
(10) Pub. No.: US 2017/0077172 A1
(43) Pub. Date: Mar. 16, 2017

(54) LIGHT-EMITTING DEVICE AND ILLUMINATION LIGHT SOURCE

(71) Applicant: Panasonic Intellectual Property Management Co., Ltd., Osaka (JP)

(72) Inventor: Keiji KIBA, Osaka (JP)

(21) Appl. No.: 15/259,702

(22) Filed: Sep. 8, 2016

(30) Foreign Application Priority Data
Sep. 10, 2015 (JP) 2015-178967

(51) Int. Cl. H01L 27/15; F21K 9/232; H01L 33/50; H01L 33/52; H01L 33/62

(52) U.S. Cl. CPC H01L 27/156; H01L 33/52; H01L 33/62; H01L 33/507; F21K 9/232

(57) ABSTRACT

A light-emitting device includes a substrate, a first light emitter that is disposed on the substrate and emits light, and a second light emitter that is disposed on the substrate and emits light of a color different from a color of the light emitted by the first light emitter. The first light emitter and the second light emitter are disposed along a periphery of the substrate.

### CROSS REFERENCE TO RELATED APPLICATION

This application claims the benefit of priority of Japanese Patent Application Number 2015-178967 filed on Sep. 10, 2015, the entire content of which is hereby incorporated by reference.

### BACKGROUND

1. Technical Field

The present disclosure relates to a light-emitting device and an illumination light source including the light-emitting device.

2. Description of the Related Art

Light-emitting diodes (LEDs) are used as light sources in a variety of products due to their high efficiency and long lifespan. In particular, research and development of lamps which use LEDs (i.e., LED lamps) as alternate illumination light sources for conventional fluorescent lamps and conventional bulb-shaped incandescent lamps is advancing.

LED lamps include, for example, an LED module including a substrate and a plurality of LEDs mounted on the substrate. For example, Japanese Unexamined Patent Application Publication No. 2013-201355 discloses a light-emitting module including a substrate and a first group of light-emitting elements that emit light of a first color and a second group of light-emitting elements that emit light of a second color mounted on the substrate.

### SUMMARY

In the conventional light-emitting module, the first group of light-emitting elements is arranged in a ring-like fashion, and the second group of light-emitting elements is disposed inside the ring of the first group of light-emitting elements. With this configuration, part of the light emitted by the second group of light-emitting elements (e.g., light rays approximately horizontal to the substrate) is blocked by the first group of light-emitting elements, which diminishes the light distribution characteristics of the light-emitting module.

In view of this, the present disclosure has an object to provide a light-emitting device and an illumination light source with improved light distribution characteristics.

In order to achieve the above object, in one aspect, a light-emitting device includes: a substrate; a first light emitter that is disposed on the substrate and emits light; and a second light emitter that is disposed on the substrate and emits light of a color different from a color of the light emitted by the first light emitter. The first light emitter and the second light emitter are alternately arranged along a periphery of the substrate.

In another aspect, a light-emitting device includes a substrate; a first light emitter that is disposed on the substrate and emits first light having a first color; and a second light emitter that is disposed on the substrate and emits second light having a second color different from the first color. The first light emitter has a first portion and a second portion. The second light emitter has a first portion and a second portion. The first portion of the first light emitter and the first portion of the second light emitter are alternately arranged along a first peripheral line of the substrate, and the second portion of the first light emitter and the second portion of the second light emitter are alternately arranged along a second peripheral line of the substrate located at an inner side of the first peripheral line.

In another aspect, a light-emitting device includes a substrate; a first light emitter that is disposed on the substrate and emits first light having a first color; and a second light emitter that is disposed on the substrate and emits second light having a second color different from the first color. The first light emitter has a first portion and a second portion. The second light emitter has a first portion and a second portion. The first portion of the first light emitter and the first portion of the second light emitter are alternately arranged along a first line, and the second portion of the first light emitter and the second portion of the second light emitter are alternately arranged along a second line parallel with the first line.

In another aspect, an illumination light source includes the above light-emitting device.

Accordingly, a light-emitting device and an illumination light source with improved light distribution characteristics can be provided.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a cross-sectional view of an illumination light source according to an embodiment;

FIG. 2 is a perspective view for illustrating the method of fixing a pedestal and an optical component together in the illumination light source according to the embodiment;

FIG. 3 is a plan view of an LED module according to the embodiment;

FIG. 4 is an enlarged view of the section indicated by circle C1 illustrated in FIG. 3;

FIG. 5 is a perspective view according to the embodiment of part of electric connection structures in a first light emitter and a second light emitter in the vicinity of a connection portion;

FIG. 6 is a plan view of an LED module according to Variation 1 of the embodiment; and

FIG. 7 is a plan view of an LED module according to Variation 2 of the embodiment.

### DETAILED DESCRIPTION OF THE EMBODIMENTS

The following describes a light-emitting device and an illumination light source according to an exemplary embodiment of the present disclosure with reference to the drawings. The exemplary embodiment described below illustrates a specific example of the present disclosure. The numerical values, shapes, materials, elements, the arrangement and connection of the elements, etc., in the following exemplary embodiment are mere examples, and therefore are not intended to limit the inventive concept. Therefore, among the elements in the following exemplary embodiment, those not recited in any of the independent claims defining the most generic part of the inventive concept are described as arbitrary elements.

Note that the drawings are represented schematically and are not necessarily precise illustrations. Additionally, like elements share like reference numerals in the drawings.

### EMBODIMENT

### Illumination Light Source

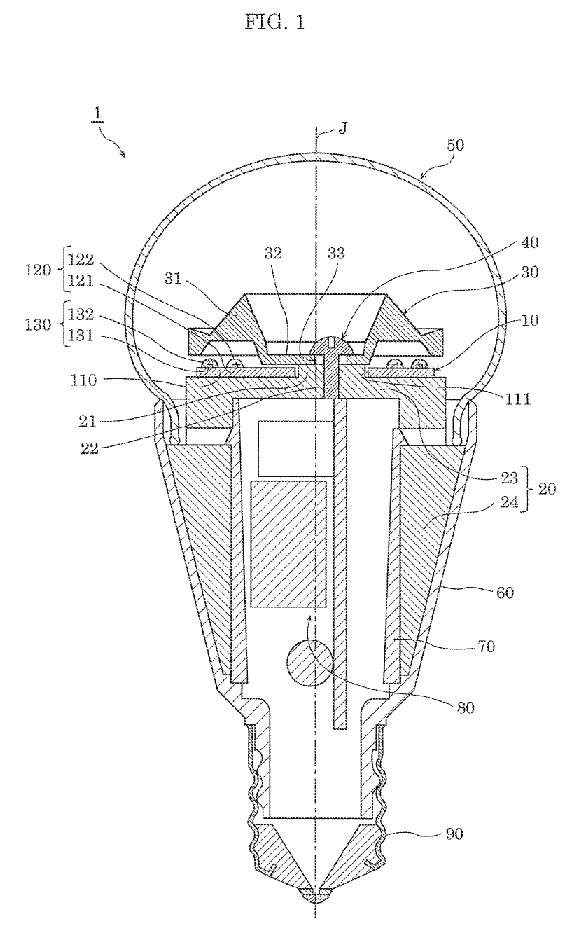

First, an outline of a light-emitting device and an illumination light source including the light-emitting device according to this embodiment will be given with reference to FIG. 1. FIG. 1 is a cross-sectional view of illumination light source 1 according to this embodiment.

Note that in FIG. 1, the vertically drawn dotted-and-dashed line represents optical axis J, which is the central axis (lamp axis) of illumination light source 1. In this embodiment, optical axis J coincides with the central axes of LED module 10, optical component 30, and globe 50. Optical axis J also the center of rotation upon attaching illumination light source 1 to the socket of a light fixture (not illustrated), and coincides with the axis of rotation of base 90.

Illumination light source 1 according to this embodiment is a bulb-shaped LED lamp (i.e., LED light bulb) used as a substitute for a bulb-shaped fluorescent or incandescent lamp. Illumination light source 1 includes LED module 10 (light-emitting device), pedestal 20, optical component 30, fixing component 40, globe 50, housing 60, circuit case 70, drive circuit 80, and base 90. The enclosure of illumination light source 1 includes globe 50, housing 60, and base 90.

Hereinafter, the elements of illumination light source 1 will be described in detail with reference to FIG. 1.

### (LED Module)

LED module 10 is a light-emitting device (light-emitting module) that emits light of a predetermined color (wavelength). In this embodiment, LED module 10 emits light of different color temperatures. More specifically, LED module 10 emits warm “L” color light (for example, incandescent light bulb color) and emits white “D” color light (for example, daylight color). In other words, illumination light source 1 according to this embodiment has a light color changing ability. For example, illumination light source 1 can switch between emitting “L” color light or “D” color light.

LED module 10 is placed on pedestal 20. LED module 10 emits light with power supplied from drive circuit 80. LED module 10 is disposed inside globe 50 so as to be covered by globe 50.

LED module 10 includes substrate 110, first light emitter 120, and second light emitter 130. Substrate 110 includes through-hole 111 into which protrusion 21 of pedestal 20 is inserted. First light emitter 120 and second light emitter 130 include a plurality of light-emitting elements and are capable of being independently turned on.

First light emitter 120 emits light of a first color temperature (for example, white “D” color light; first light having a first color). First light emitter 120 includes first LEDs 121 and first sealant 122.

Second light emitter 130 emits light of a second color temperature (for example, warm “L” color light; second light having a second color). Second light emitter 130 includes second LEDs 131 and second sealant 132.

LED module 10 according to this embodiment has a chip-on-board (COB) structure in which first LEDs 121 and second LEDs 131, which are bare chips, are directly mounted on substrate 110. Although not illustrated in the drawings, note that LED module 10 further includes metal lines patterned on substrate 110 in a predetermined pattern, wires electrically connecting the LED chips, and protective elements (for example, Zener diodes) that protect the LED chips from static electricity.

Each element of LED module 10 will be described in detail later.

### (Pedestal)

Pedestal 20 is a support base that supports LED module 10. Pedestal 20 includes a placement surface for placing LED module 10 (i.e., an LED module installation surface). More specifically, substrate 110 of LED module 10 is placed on the placement surface.

Note that pedestal 20 functions as a heat sink that dissipates heat generated by LED module 10. As such, pedestal 20 includes, for example, a metal such as aluminum, or a resin having a high rate of heat transfer.

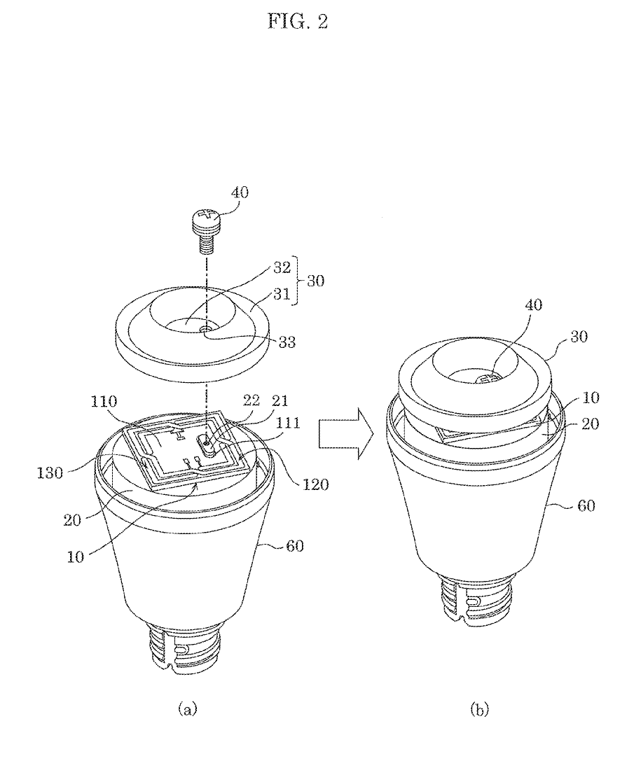

Pedestal 20 includes protrusion (boss) 21 that protrudes toward component 30. As illustrated in FIG. 2, protrusion 21 is inserted in through-hole 111 provided in substrate 110. Note that FIG. 2 is a perspective view for illustrating the method of fixing pedestal 20 and optical component 30 together in illumination light source 1 according to this embodiment.

In this embodiment, the peak of protrusion 21 is designed to protrude out from through-hole 111 when protrusion 21 is inserted in through-hole, as illustrated in FIG. 1 and FIG. 2. In other words, the height of protrusion 21 measured from the placement surface is greater than the thickness of substrate 110.

Protrusion 21 includes fixing hole 22. Fixing hole 22 is a hole for securing fixing component 40. When fixing component 40 is a screw, fixing hole 22 is a screw hole with a threaded inner wall.

Note that pedestal 20 according to this embodiment extends into the interior of housing 60. Pedestal 20 includes placement portion 23 and tubular portion 24. Placement portion 23 is approximately circular in shape and plate-like in form, and is the portion on which LED module 10 is placed on. Tubular portion 23 is approximately cylindrical in shape and is surrounded by housing 60. The outer surface of tubular portion 24 is in contact with the inner surface of housing 60, and the inner surface of tubular portion 24 is in contact with circuit case 70.

### (Optical Component)

Optical component 30 is a lens (light distribution control lens) that controls the distribution of light emitted from the light emitters (first light emitter 120 and second light emitter 130) of LED module 10. Optical component 30 includes, for example, a light-transmissive resin. The light-transmissive resin may be, for example, acryl (PMMA) or polycarbonate (PC).

Note that the optical axis of optical component 30 coincides with the optical axis of LED module 10. Moreover, optical component 30 is so shaped as not to block light emitted in an outer peripheral direction from LED module 10.

As illustrated in FIG. 1 and FIG. 2, optical component 30 includes lens portion 31 and attachment portion 32. Lens portion 31 and attachment portion 32 can be integrally formed from resin.

Lens portion 31 is disposed across from first light emitter 120 and second light emitter 130. Lens portion 31 is shaped so as to achieve a desired distribution of light emitted from first light emitter 120 and second light emitter 130. For example, lens portion 31 is formed so as to increase the distribution angle of light of illumination light source 1 by refracting (for example, converging or diverging) or reflecting light from LED module 10.

Attachment portion 32 has the shape of, for example, a flat plate, and is in contact with pedestal 20. In this embodiment, the bottom surface of attachment portion 32 is in contact with the top surface of protrusion 21 of pedestal 20.

Attachment portion 32 includes insertion hole 33 through which fixing component 40 is inserted. The diameter of the opening of insertion hole 33 is greater than the diameter of the opening of fixing hole 22 and less than the outer diameter of the screw head of fixing component 40 (when fixing component 40 is a screw). The central axis of insertion hole 33 and the central axis of fixing hole 22 coincide with each other.

### (Fixing Component)

Fixing component 40 is a fastener such as a screw. As illustrated in FIG. 2, fixing component 40 fastens and fixes pedestal 20 and optical component 30 together via through-hole 111 of substrate 110. Note that in this embodiment, fixing component 40 is exemplified as a screw, but when fixing hole 22 is a through-hole, fixing component 40 may be a nut and bolt.

More specifically, as illustrated in (a) in FIG. 2, LED module 10 is placed on pedestal 20 so that protrusion 21 is inserted in through-hole 111 of substrate 110. At this time, substrate 110 and pedestal 20 are fixed together with an adhesive (not illustrated in the drawings). Next, as illustrated in (b) in FIG. 2, optical component 30 is placed on protrusion 21 so that the rear surface of attachment portion 32 of optical component 30 is in contact with the top surface of protrusion 21. Then, fixing component 40 is screwed into insertion hole 33 of optical component 30 and fixing hole 22 of protrusion 21 to fix optical component 30 and pedestal 20 together.

### (Globe)

Globe 50 is a light-transmissive cover that covers LED) module 10 and optical component 30. Globe 50 is formed so as to extract out of the lamp light directly emitted by LED module 10 and light emitted by LED module 10 and transmitted by optical component 30. In other words, light incident on the inner surface of globe 50 passes through and is extracted out of globe 50.

Globe 50 is a hollow component with an opening section at one end and peak section at the opposite end that is closed. Globe 50 is, for example, a hollow body of revolution whose axis coincides with optical axis J. In this embodiment, globe 50 is formed into an approximate hemisphere whose opening section is formed so as to extrude from the hemispherical shape.

Globe 50 is disposed so as to be supported by pedestal 20 and disposed such that the opening section is in contact with the surface of pedestal 20. The opening section of globe 50 is attached to pedestal 20 and the inner surface of housing 60 with an adhesive such as silicon resin.

Globe 50 may have light diffusing characteristics. In this case, globe 50 can transmit out light evenly.

### (Housing)

Housing 60 forms the outer silhouette of illumination light source 1, and the outer surface of housing 60 is exposed to the outside of the lamp (i.e., to the atmosphere). Housing 60 includes, for example, an electrically insulating resin such as polybutylene terephthalate (PBT).

Housing 60 is a tubular body formed so as to surround tubular portion 24 of pedestal 20. Housing 60 includes a base attachment portion having an outer surface with threads for screwing together with base 90. Base 90 is fixed to housing 60 by being screwed together with the base attachment portion.

### (Circuit Case)

Circuit case 70 is an electrically insulating case formed so as to surround drive circuit 80. Circuit case 70 includes, for example, an electrically insulating resin such as polybutylene terephthalate (PBT). Circuit case 70 includes, for example, a claw section (not illustrated in the drawings) for holding a circuit substrate of drive circuit 80.

Circuit case 70 is fixed to the inside of tubular portion 24 of pedestal 20. For example, circuit case 70 includes the claw section on the outer surface, and is supported by pedestal 20 as a result of the claw section hooking into a hole formed in tubular portion 24 of pedestal 20.

### (Drive Circuit)

Drive circuit (circuit unit) 80 is a lighting circuit for causing LED module 10 (first LEDs 121 and second LEDs 131) to emit light (turn on). Drive circuit 80 supplies LED module 10 with predetermined power. Drive circuit 80 converts alternating current power supplied from base 90 via a lead line (not illustrated in the drawings) into direct current power. Drive circuit 80 supplies LED module 10 with the converted direct current power via a different lead line (not illustrated in the drawings).

Drive circuit 80 includes, for example, a circuit substrate and a plurality of circuit elements (electronic components) for turning on LED module 10. Each circuit element is mounted on the circuit substrate.

In this embodiment, drive circuit 80 independently drives first light emitter 120 and second light emitter 130 of LED module 10. In other words, drive circuit 80 controls the starting and stopping the supply of power to first light emitter 120 and second light emitter 130 independently. When drive circuit 80 only supplies power to first light emitter 120, LED module 10 (illumination light source 1) emits, for example, “D” color light. When drive circuit 80 only supplies power to second light emitter 130, LED module 10 emits, for example, “L” color light.

### (Base)

Base 90 receives, from a source external to the lamp, power for causing LED module 10 (first LEDs 121 and second LEDs 131) to emit light. Base 90 is, for example, attached to the socket of a light fixture (not illustrated in the drawings). As a result, base 90 can receive power from the socket of the light fixture when illumination light source 1 is to be illuminated. For example, base 90 is supplied with alternating current power from an AC 100V utility power supply, and supplies the power to drive circuit 80 via a lead line (not illustrated in the drawings).

Base 90 is not limited to any particular type of base, but in this embodiment, base 90 is exemplified as an Edison (E) screw type of base. For example, base 90 may be an E26, E17, or E16 type of base. Note that base 90 may be a plug-in type of base (for example, a G, GU, or GX type of base).

### (LED Module (Light-Emitting Device))

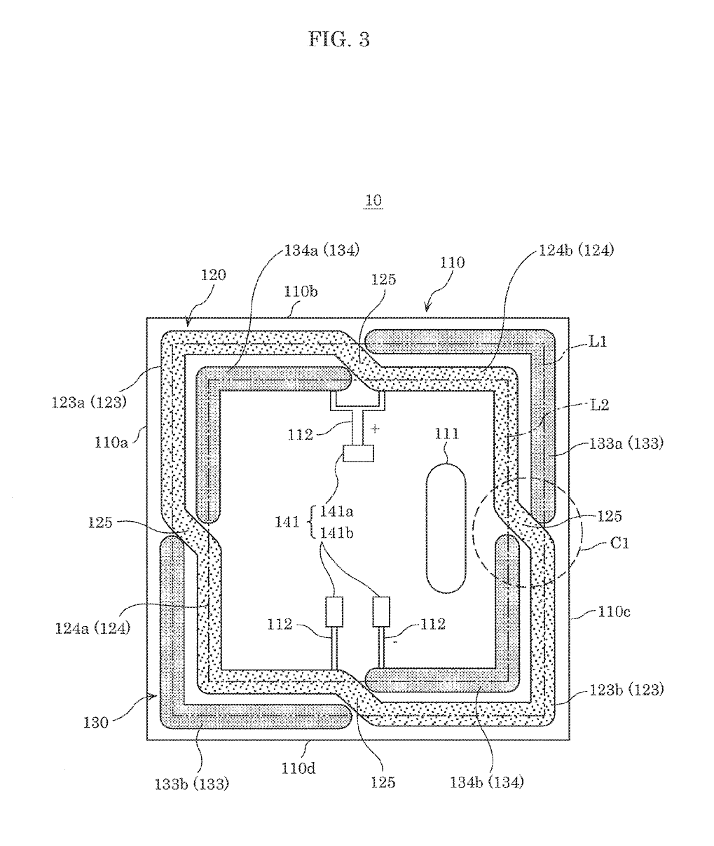

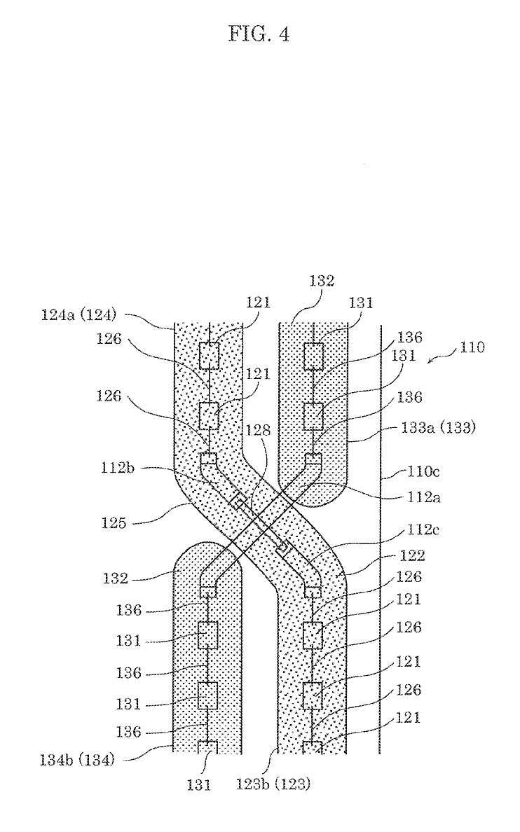

Next, LED module 10 (the light-emitting device) according to this embodiment will be described in detail with reference to FIG. 3 and FIG. 4. FIG. 3 is a plan view of LED module 10 according to this embodiment. FIG. 4 is an enlarged view of section C1 illustrated in FIG. 3.

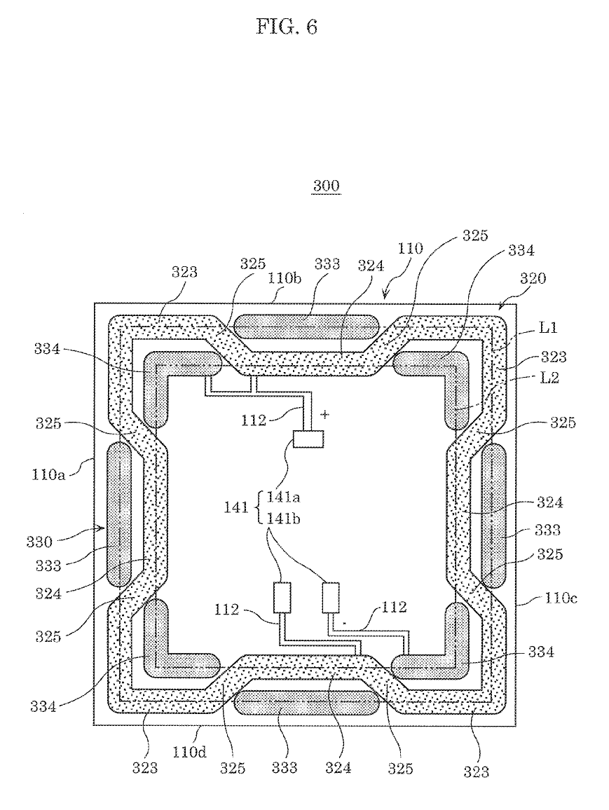

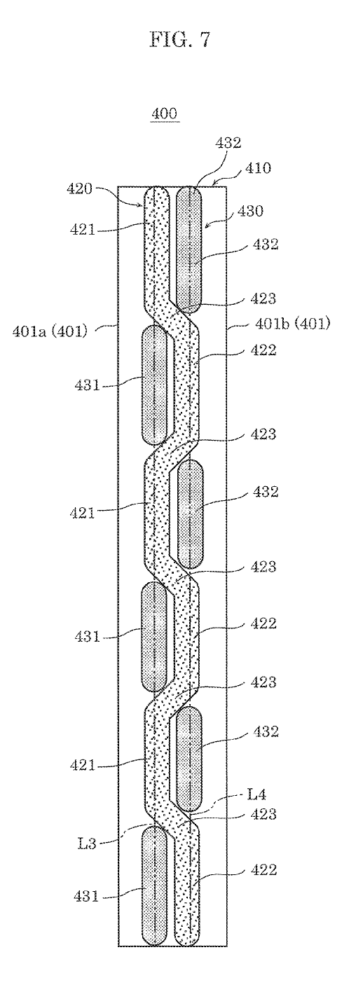

Note that in FIG. 3 and FIG. 4, first light emitter 120 is shaded with coarse dots and second light emitter 130 is shaded with fine dots. The same applies to FIG. 6 and FIG. 7, which will be described later.

### (Substrate)

Substrate 110 is an LED mounting substrate for mounting first LEDs 121 and second LEDs 131. Substrate 110 is, for example, an electrically insulated substrate such as a ceramic substrate, a resin substrate, or a glass substrate. Alternatively, substrate 110 may be a metal-based substrate (metal substrate) configured of a metal plate covered with an electrically insulating film.

A white substrate having a high optical reflectivity (for example, an optical reflectivity of 90% or higher) may be used as substrate 110. By using a white substrate, light from first LEDs 121 and second LEDs 131 can be reflected off the surface of substrate 110, thereby increasing light extraction efficiency. For example, a white ceramic substrate including alumina (i.e., a white alumina substrate) can be used as substrate 110.

As illustrated in FIG. 1, substrate 110 is disposed on pedestal 20. More specifically, substrate 110 is placed on and fixed to pedestal 20. For example, substrate 110 is fixed to pedestal 20 with an adhesive such as silicon resin.

Substrate 110 has, for example, a square shape in a plan view, as illustrated in FIG. 3. Substrate 110 may have, in a plan view, a quadrilateral shape such as a rectangle, a polygonal shape such as a hexagon, or some other shape such as a circle.

As illustrated in FIG. 3, substrate 110 includes power receiver 141.

Power receiver 141 is a terminal that receives power to be supplied to first light emitter 120 and second light emitter 130. Power receiver 141 is connected to drive circuit 80 via a lead line (not illustrated in the drawings), and receives direct current power from drive circuit 80. Power receiver 141 is electrically connected to first light emitter 120 and second light emitter 130 via metal line 112 patterned on substrate 110. More specifically, power receiver 141 includes positive terminal 141a and a pair of negative terminals 141b. Metal line 112 is connected to positive terminal 141a and branches so as to be electrically connected to first light emitter 120 and second light emitter 130. Metal line 112, which is individually connected to first light emitter 120 and second light emitter 130, is electrically connected to pair of negative terminals 141b.

### (First Light Emitter)

First light emitter 120 emits light of a first color temperature. The first color temperature is higher than the second color temperature of light emitted by second light emitter 130. For example, the first color temperature is 8000 K. In other words, first light emitter 120 emits “D” color white light (for example daylight color).

As illustrated in FIG. 4, first light emitter 120 includes a plurality of first LEDs 121 and first sealant 122.

First LEDs 121 are one example of the plurality of first light-emitting elements, and are LED chips directly mounted on substrate 110. First LEDs 121 are arranged in, for example, a line. First LEDs 121 are, for example, blue LED chips that emit blue light when supplied with power. First LEDs 121 are mainly connected in series in a chip-to-chip configuration by bonding wires 126.

First sealant 122 is a phosphor-containing resin, and the phosphor contained in the resin functions as an optical wavelength converter. First sealant 122 converts the light from first LEDs 121 into light of a predetermined wavelength (i.e., converts the color). First sealant 122 protects first LEDs 121 by sealing first LEDs 121.

First sealant 122 includes a material selected based on the color (wavelength) of light emitted by first LEDs 121 and the desired color (wavelength) of light to be achieved as a light source. For example, in order to obtain white light when first LEDs 121 are blue LED chips, a phosphor-containing resin configured of YAG (yttrium aluminum garnet) yellow phosphor particles dispersed in a silicon resin can be used as first sealant 122.

With this, the yellow phosphor particles are excited by the blue light from the blue LED chips and emit yellow light, which mixes with the blue light from the LED chips such that white light having the first color temperature is emitted from first sealant 122. Note that first sealant 122 may include red phosphor particles to adjust the color of the white light. Moreover, first sealant 122 may include a light diffusing material such as silica (SiO₂).

### (Second Light Emitter)

Second light emitter 130 emits light of a second color temperature. The second color temperature is lower than the second color temperature of light emitted by first light emitter 120. For example, the second color temperature is in a range of 2200 K to 2500 K. In other words, second light emitter 130 emits “L” warm color light (for example incandescent light bulb color). In this way, second light emitter 130 emits light of a different color than the light emitted by first light emitter 120.

Second LEDs 131 are one example of the plurality of second light-emitting elements, and are LED chips directly mounted on substrate 110. Second LEDs 131 are arranged in, for example, a line. Second LEDs 131 are, for example, blue LED chips that emit blue light when supplied with power. Second LEDs 131 are mainly connected in series in a chip-to-chip configuration by bonding wires 136.

Second sealant 132 is, for example, a phosphor-containing resin just like first sealant 122, but includes a different phosphor than first sealant 122. For example, second sealant 132 includes red phosphor particles instead of yellow phosphor particles. Alternatively, when first sealant 122 includes red phosphor particles, second sealant 132 includes more red phosphor particles than first sealant 122. In other words, the concentration of phosphor contained in second sealant 132 is greater than the concentration of phosphor contained in first sealant 122 as a result of second sealant 132 including more phosphor than first sealant 122. Stated differently, first sealant 122 has a lower phosphor concentration than second sealant 132.

With this, the mixed light from second sealant 132 can be made to include more red components, and thus made to have a lower color temperature. Consequently, second sealant 132 emits light of a second color temperature.

Note that second LEDs 131 may be the same as first LEDs 121. In other words, the difference in color temperature of light from first light emitter 120 and second light emitter 130 can be achieved by changing the phosphor material used in first sealant 122 and second sealant 132.

### (Arrangement)

Next, the arrangement on substrate 110 of first light emitter 120 and second light emitter 130 according to this embodiment will be described.

As illustrated in FIG. 3, at each edge 110a, 110b, 110c, and 110d of substrate 110, first light emitter 120 and second light emitter 130 alternate in adjacency to the edge. FIG. 3 illustrates rectangular ring-shaped virtual lines L1 and L2 located in more inward positions than edges 110a, 110b, 110c, and 110d of substrate 110. Virtual line L2 (second peripheral line; second line) is located in a more inward position than virtual line L1 (first peripheral line; first line) and is parallel to virtual line L1.

Regarding the meaning of “adjacent”, taking first light emitter 120 as example, “adjacent” means that second light emitter 130 is not present between edge 110a, 110b, 110c, or 110d of substrate 110 and first light emitter 120. In addition to second light emitter 130, other elements that would block light from first light emitter 120 are preferably not disposed between edge 110a, 110b, 110c, or 110d of substrate 110 and first light emitter 120. Stated differently, a component that does not greatly block light from first light emitter 120 (such as a circuit component or circuit element) may be disposed between edge 110a, 110b, 110c, or 110d of substrate 110 and first light emitter 120.

First light emitter 120 has an overall shape of a continuous ring. First light emitter 120 includes two first exterior portions 123 (first portions) and two first interior portions 124 (second portions).

The two first exterior portions 123 are formed on virtual line L1. More specifically, first exterior portion 123a among the two first exterior portions 123 is formed in an L-shape on virtual line L1 so as to be adjacent to edges 110a and 110b that define one corner of substrate 110. One end of first exterior portion 123a is located at the central region of edge 110a, and the other end of first exterior portion 123a is located at the central region of edge 110b. First exterior portion 123b, which is the other of the two first exterior portions 123, is formed in an L-shape on virtual line L1 so as to be adjacent to edges 110c and 11d that define one corner of substrate 110. One end of first exterior portion 123b is located at the central region of edge 110c, and the other end of first exterior portion 123a is located at the central region of edge 110d.

The two first interior portions 124 are formed on virtual line L2. More specifically, first interior portion 124a among the two first interior portions 124 is formed in an L-shape on virtual line L2 so as to be formed along edges 110a and 110d that define one corner of substrate 110, with virtual line L1 disposed between first interior portion 124a and edges 110a and 110d. One end of first interior portion 124a is located at the central region of edge 110a, and the other end of first interior portion 124a is located at the central region of edge 110d. First interior portion 124b, which is the other of the two first interior portions 124, is formed in an L-shape on virtual line L2 so as to be formed along edges 110b and 110c that define one corner of substrate 110, with virtual line L1 disposed between first interior portion 124b and edges 110b and 110c. One end of first interior portion 124b is located at the central region of edge 110b, and the other end of first interior portion 124b is located at the central region of edge 110c.

Connection portion 125 is located between an end of first exterior portion 123 and an end of first interior portion 124. Connection portions 125 are formed across virtual line L1 and virtual line L2, and integrally connect first exterior portions 123 and first interior portions 124. With this, since the two first exterior portions 123 and the two first interior portions 124 are connected together by connection portions 125, first light emitter 120 has an overall shape of a continuous ring.

Second light emitter 130 has an overall shape of a discontinuous ring. Second light emitter 130 includes two second exterior portions 133 (first portions) and two second interior portions 134 (second portions).

The two second exterior portions 133 are formed on virtual line L1 so as not to overlap with first exterior portions 123 of first light emitter 120 in a plan view. More specifically, second exterior portion 133a among the two second exterior portions 133 is formed on virtual line L1 so as to be adjacent to edges 110b and 110c that define one corner of substrate 110. One end of second exterior portion 133a is located at the central region of edge 110b, and the other end of second exterior portion 133a is located at the central region of edge 110c. Second exterior portion 133b, which is the other of the two second exterior portions 133, is formed on virtual line L1 so as to be adjacent to edges 110a and 110d that define one corner of substrate 110. One end of second exterior portion 133b is located at the central region of edge 110a, and the other end of second exterior portion 133b is located at the central region of edge 110d.

The two second interior portions 134 are formed on virtual line L2 so as not to overlap with first interior portions 124 of first light emitter 120 in a plan view. More specifically, second interior portion 134a among the two second interior portions 134 is formed on virtual line L2, along edges 110a and 110b that define one corner of substrate 110, with virtual line L1 disposed between second interior portion 134a and edges 110a and 110b. One end of second interior portion 134a is located at the central region of edge 110a, and the other end of second interior portion 134a is located at the central region of edge 110b. Second interior portion 134b, which is the other of the two second interior portions 134, is formed on virtual line L2, along edges 110c and 110d that define one corner of substrate 110, with virtual line L1 disposed between second interior portion 134b and edges 110c and 110d. One end of second interior portion 134b is located at the central region of edge 110c, and the other end of second interior portion 134b is located at the central region of edge 110d.

By arranging first light emitter 120 and second light emitter 130 in this manner, first exterior portions 123 of first light emitter 120 and second exterior portions 133 of second light emitter 130 alternate in adjacency to each edge 110a, 110b, 110c, and 110d of substrate 110. With this, part of the light from first exterior portions 123 of first light emitter 120 (e.g., light rays approximately horizontal to substrate 110) is emitted out without being blocked by second light emitter 130. Moreover, part of the light from second exterior portions 133 of second light emitter 130 is emitted out without being blocked by first light emitter 120.

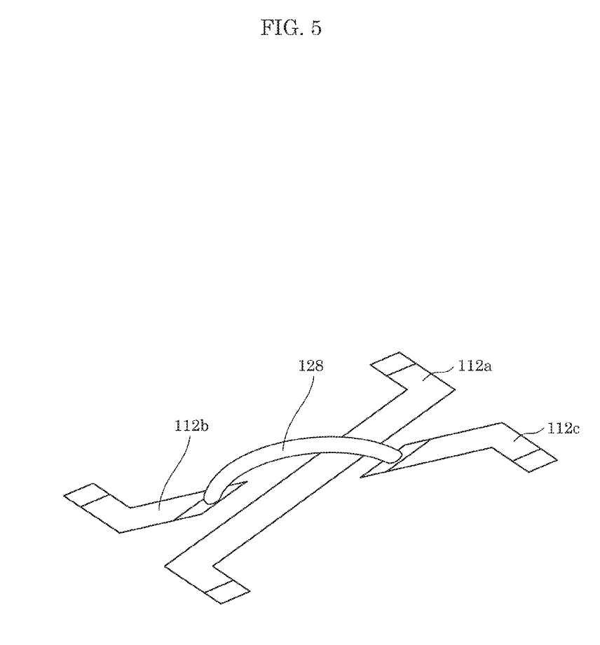

Next, the electric connection structures in first light emitter 120 and second light emitter 130 in the vicinity of connection portion 125 will be described with reference to FIG. 4 and FIG. 5.

FIG. 5 is a perspective view according to this embodiment of part of the electric connection structures in first light emitter 120 and second light emitter 130 in the vicinity of connection portion 125.

The region corresponding to edge 110c of substrate 110 will be used as an example in this description, but the following also applies to regions corresponding to other edges (110a, 110b, and 110d) as well. As illustrated in FIG. 4, in the vicinity of connection portion 125, the light emitter that is adjacent edge 110c of substrate 110 switches from first light emitter 120 to second light emitter 130 or vice versa. In this location, since the electric connection structure in first light emitter 120 and the electric connection structure in second light emitter 130 cross paths, a structure that prevents electrical interference between the two is required.

First, the electric connection structure in second light emitter 130 will be described.

As illustrated in FIG. 4 and FIG. 5, substrate 110 includes second wiring pattern 112a (connecting pattern) located between an end of second exterior portion 133a of second light emitter 130 and an end of second interior portion 134b of second light emitter 130. Note that first wiring patterns 112b and 122c will be described later.

Second wiring pattern 112a is an elongated metal line formed roughly diagonal to edge 110c. One end of second wiring pattern 112a is connected to second LED 131 located at the end of second exterior portion 133a via bonding wire 136. The other end of second wiring pattern 112a is connected to second LED 131 located at the end of second interior portion 134b via bonding wire 136. With this, second LEDs 131 in second exterior portion 133a and second LEDs 131 in second interior portion 134b are electrically connected via second wiring pattern 112a.

Next, the electric connection structure in first light emitter 120 will be described.

Substrate 110 includes a pair of first wiring patterns 112b and 112c disposed in a location corresponding to connection portion 125 of first light emitter 120, and arranged across from each other with second wiring pattern 112a therebetween. First wiring patterns 122b and 112c are metal lines formed roughly along a direction intersecting the long direction of second wiring pattern 112a. First wiring pattern 112b among the pair of first wiring patterns 112b and 112c is disposed on the first interior portion 124a side. A first end of first wiring pattern 112b (the end nearest first interior portion 124a) is connected to first LED 121 located at the end of first interior portion 124a via bonding wire 126.

First wiring pattern 112c among the pair of first wiring patterns 112b and 112c is disposed on the first exterior portion 123b side. A first end of first wiring pattern 112c (the end nearest first exterior portion 123b) is connected to first LED 121 located at the end of first exterior portion 123b via bonding wire 126.

The pair of first wiring patterns 112b and 112c are electrically connected together by conductor 128, one example of which is a jumper wire. More specifically, the second end of first wiring pattern 112b is connected to the first end of conductor 128, and the second end of wiring pattern 112c is connected to the second end of conductor 128. Conductor 128 is arched such that the central portion of conductor 128 is spaced from second wiring pattern 112a. In other words, second wiring pattern 112a passes under first light emitter 120. As a result, conductor 128 does not contact second wiring pattern 112a.

Moreover, as illustrated in FIG. 4, conductor 128 of first light emitter 120 is sealed by first sealant 122. As such, the form of conductor 128 is maintained by first sealant 122, whereby conductor 128 can be held long-term in a state in which conductor 128 does not contact second wiring pattern 112a.

In this manner, first LEDs 121 in first exterior portion 123b are electrically connected with first LEDs 121 in first interior portion 124a by conductor 128.

### (Advantageous Effects, Etc.)

As described above, in LED module 10 (the light-emitting device) according to this embodiment, first light emitter 120 and second light emitter 130 are disposed along at least part of the periphery of substrate 110 (along all edges 110a, 110b, 110c, and 110d of substrate 110 in this embodiment). More specifically, first exterior portions 123 of first light emitter 120 and second exterior portions 133 of second light emitter 130 alternate in adjacency to each edge 110a, 110b, 110c, and 110d of substrate 110. With this, part of the light from first exterior portions 123 of first light emitter 120 (e.g., light rays approximately horizontal to substrate 110) is emitted out without being blocked by second light emitter 130. Similarly, part of the light from second exterior portions 133 of second light emitter 130 is emitted out without being blocked by first light emitter 120. Thus, light distribution characteristics can be improved.

This advantageous effect is notable when globe 50 has light diffusing characteristics. More specifically, unevenness in color and luminance of diffused light emitted from globe 50 can be reduced.

Moreover, first light emitter 120 and second light emitter 130 each include a plurality of light-emitting elements arranged in a line. Since first light emitter 120 and second light emitter 130 are thus each formed in line, a grainy appearance can be reduced more so than when a point light source arrangement is used.

Moreover, at locations along each edge 110a, 110b, 110c, and 110d of substrate 110 where the light emitter that is adjacent the edge switches from first light emitter 120 to second light emitter 130 or vice versa, second LEDs 131 are electrically connected by second wiring pattern 112a, and first LEDs 121 are electrically connected by conductor 128. Since first LEDs 121 are electrically connected by second wiring pattern 112a at these locations, the electric connection structure in first light emitter 120 can be simplified compared to when first LEDs 121 are electrically connected by a conductor as well.

Moreover, conductor 128 of first light emitter 120 is sealed by first sealant 122. As such, the form of conductor 128 is maintained by first sealant 122, whereby conductor 128 can be held long-term in a state in which conductor 128 does not contact second wiring pattern 112a.

Moreover, since first sealant 122, which seals conductor 128, can be formed so as to be continuous throughout, compared to when first sealant 122 is formed discontinuously, first sealant 122 can be formed in one go, which increases manufacturing efficiency.

Moreover, since first sealant 122, which has a lower concentration of phosphor than second sealant 132, is formed continuously throughout, compared to when second sealant 132 is formed continuously, the amount of phosphor used can be reduced. Thus, manufacturing costs can be reduced.

### (Variation 1)

Next, Variation 1 of the LED module (the light-emitting device) according to the embodiment will be described with reference to FIG. 6. Note that since like configurations in the following description and the above embodiment share like reference numerals, description of those configurations may be omitted.

FIG. 6 is a plan view of LED module 300 according to this variation.

As illustrated in FIG. 6, in LED module 300, first light emitter 320 alone is disposed adjacent every corner defined by edges 110a, 110b, 110c, and 110d of substrate 110. Described more specifically, first light emitter 320 has an overall shape of a continuous ring. First light emitter 320 includes four first exterior portions 323 and four first interior portions 324.

The four first exterior portions 323 are disposed in the vicinity of the corners defined by edges 110a, 110b, 110c, and 110d of substrate 110. Each of the four first exterior portions 323 is formed in an L-shape on virtual line L1. The four first exterior portions 323 are disposed adjacent edges 110a, 110b, 110c, and 110d.

Each of the four first interior portions 324 is disposed between two neighboring first exterior portions 323. The four first interior portions 324 are formed in straight lines on virtual line L2.

Connection portion 325 is located between an end of first exterior portion 323 and an end of first interior portion 324. Connection portions 125 are formed across virtual line L1 and virtual line L2, and integrally connect first exterior portions 323 and first interior portions 324.

Second light emitter 330 has an overall shape of a discontinuous ring. Second light emitter 330 includes four second exterior portions 333 and four second interior portions 334.

The four second exterior portions 333 are formed in straight lines on virtual line L1 so as not to overlap with first exterior portions 323 of first light emitter 320 in a plan view. Each second exterior portion 333 is disposed between two neighboring first exterior portions 323. The four second exterior portions 333 are disposed adjacent edges 110a, 110b, 110c, and 110d.

The four second interior portions 334 are formed in an L-shape on virtual line L2 so as not to overlap with first interior portions 324 in a plan view.

Note that at locations along each edge 110a, 110b, 110c, and 110d of substrate 110 where the light emitter that is adjacent the edge switches from first light emitter 320 to second light emitter 330 or vice versa, the same electric connection structures as the above embodiment are used.

Since first light emitter 320 alone is disposed adjacent every corner defined by edges 110a, 110b, 110c, and 110d of substrate 110, light rays emitted horizontal to substrate 110 can be homogenized, and light distribution characteristics can be increased.

When globe 50 has light diffusing characteristics in particular, unevenness in color and luminance of diffused light emitted from globe 50 can be further reduced.

Moreover, in the above embodiment, along each edge 110a, 110b, 110c, and 110d of substrate 110, first light emitter 120 and second light emitter 130 are disposed adjacent the edge at one location each. However, in this variation, second light emitter 330 is adjacent each edge in only one location, and first light emitter 320 is adjacent each edge in two locations. By increasing the number of locations in which first light emitter 320 and second light emitter 330 are adjacent edges 110a, 110b, 110c, and 110d, the effectiveness of the reduction in unevenness in color and luminance can be increased. However, if the number of locations of adjacency are increased too much, the number of connection portions 325 also increases, meaning the number of regions in which light is not produced increases, which may lead to unevenness in color and luminance. As such, determining a layout for first light emitter 320 and second light emitter 330 that is optically balanced through various tests and simulations is preferable.

### (Variation 2)

FIG. 7 is a plan view of LED module 400 according to this variation.

As illustrated in FIG. 7, LED module 400 according to this variation is what is known as a line module. Substrate 410 of LED module 400 is an elongated substrate. First light emitter 420 and second light emitter 430 are disposed on substrate 410, along long side 401 of substrate 410.

Here, in FIG. 7, virtual lines L3 and L4 are illustrated parallel to long side 401 on substrate 410. Virtual lines L3 and L4 are spaced apart from each other.

First light emitter 420 is formed in a staggered arrangement along long side 401. As such, first light emitter 420 includes first section 421 nearest long side 401a among the pair of long sides 401a and 401b of substrate 410, and second section 422 nearest long side 401b among the pair of long sides 401a and 401b of substrate 410. First section 421 and second section 422 are formed in lines parallel to long side 401. First section 421 is formed on virtual line L3 and second section 422 is formed on virtual line L4.

First section 421 and second section 422 are connected by connecting portion 423. Connecting portion 423 is formed in a line diagonal to long side 401.

Second light emitter 430 is formed, as a whole, discontinuously in a tortuous manner along long side 401. As such, second light emitter 430 includes third section 431 nearest long side 401a, and fourth section 432 nearest long side 401b. Third section 431 and fourth section 432 are formed in lines parallel to long side 401. Third section 431 is formed on virtual line L3 so as not to overlap with first light emitter 420 in a plan view. Fourth section 432 is formed on virtual line L4 so as not to overlap with first light emitter 420 in a plan view.

By disposing first light emitter 420 and second light emitter 430 in this manner, first section 421 of first light emitter 420 and third section 431 of second light emitter 430 are alternately adjacent long side 401a of substrate 410. Similarly, second section 422 of first light emitter 420 and fourth section 432 of second light emitter 430 are alternately adjacent long side 401b of substrate 410. With this, in a side view of long side 401a, part of the light from first section 421 of first light emitter 420 (e.g., light rays approximately horizontal to substrate 410) is emitted out beyond long side 401a without being blocked by second light emitter 430. Similarly, part of the light from third section 431 of second light emitter 430 is emitted out beyond long side 401a without being blocked by first light emitter 420.

In a side view of long side 401b, part of the light from second section 422 of first light emitter 420 is emitted out beyond long side 401b without being blocked by second light emitter 430. Similarly, part of the light from fourth section 432 of second light emitter 430 is emitted out beyond long side 401b without being blocked by first light emitter 420.

Thus, even in LED module 400, which is a line module, light distribution characteristics can be improved.

Note that at locations along each long side 401a and 401b of substrate 410 where the light emitter that is adjacent the edge switches from first light emitter 420 to second light emitter 430 or vice versa, the same electric connection structures as the above embodiment are used.

### (Other Variations)

The light-emitting device and illumination light source including the light-emitting device according to the present disclosure have herein been described based on the above embodiment and variations thereof, but the light-emitting device and illumination light source including the light-emitting device according to the present disclosure is not limited to the above embodiment and variations thereof.

For example, in the above embodiment, first light emitter 120 and second light emitter 130 are exemplified as line-shaped light emitters, but first light emitter 120 and second light emitter 130 may be dotted light emitters.

Moreover, the layout of first light emitter 120, 320, 420 and second light emitter 130, 330, and 430 according to the above embodiment and variations thereof may be reversed.

Moreover, in the above embodiment, the color temperature of light emitted by first light emitter 120 and second light emitter 130 is made to be different by forming first sealant 122 and second sealant 132 to be different, but this example is not limiting. For example, second LEDs 131 may emit light that includes more red components than first LEDs 121.

Alternatively, instead of all second LEDs 131 included in second light emitter 130 being blue LED chips, some of second LEDs 131 may be red LED chips. The same applies to first light emitter 120. In this case, for example, the number of red LED chips included in second light emitter 130 may be greater than the number of red LED chips included in first light emitter 120.

Moreover, for example, in the above embodiment, first light emitter 120 and second light emitter 130 are exemplified as being disposed in straight lines, but this example is not limiting. For example, when first light emitter and second light emitter are disposed on a substrate having a curved periphery, such as a circular or elliptical substrate, first light emitter and second light emitter may be disposed on a curved line that follows the periphery of the substrate.

Moreover, for example, LED module 10 may include a third light emitter that emits light of a different color than the first light emitter and the second light emitter. In this case, the first light emitter, the second light emitter, and the third light emitter may be arranged adjacent to the periphery of the substrate.

Moreover, in the above embodiment, electric connection structures for preventing first light emitter 120 and second light emitter 130 from electrically interfering with one another are exemplified second wiring pattern 112a and conductor 128. However, any electric connection structure that prevents first light emitter 120 and second light emitter 130 from electrically interfering with one another may be used. For example, an electric connection structure in which the electrical connection line of first light emitter 120 and the electrical connection line of second light emitter 130 are independent from each other via a multi-player substrate may be used.

Moreover, for example, in the above embodiment, the light-emitting elements are exemplified as LEDs, but the light-emitting elements are not limited to this example. The light-emitting elements may be semiconductor light-emitting elements such as semiconductor lasers, or solid-state light-emitting elements such as organic or non-organic electroluminescent (EL) elements.

Moreover, for example, in the above embodiment, illumination light source 1 including LED module 10 is exemplified as a bulb-shaped lamp, but illumination light source 1 is not limited to this example. Illumination light source 1 may be a straight tube LED lamp. Alternatively, LED module 10 may be applied in a variety of luminaires, such as downlights, spotlights, ceiling lights, and pendant lights.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A light-emitting device, comprising:
a substrate;
a first light emitter that is disposed on the substrate and emits light; and
a second light emitter that is disposed on the substrate and emits light of a color different from a color of the light emitted by the first light emitter,
wherein the first light emitter and the second light emitter are alternately arranged along a periphery of the substrate.

2. The light-emitting device according to claim 1, wherein:
the first light emitter includes a plurality of first light-emitting elements arranged in a line and a first sealant that seals the plurality of first light-emitting elements and emits fluorescent light when illuminated by light from the plurality of first light-emitting elements, and
the second light emitter includes a plurality of second light-emitting elements arranged in a line and a second sealant that seals the plurality of second light-emitting elements and emits fluorescent light when illuminated by light from the plurality of second light-emitting elements.

3. The light-emitting device according to claim 2, wherein in an area in which the first light emitter and the second light emitter cross paths, two light-emitting elements of the plurality of first light-emitting elements are electrically connected by a wiring pattern formed on the substrate, and two light-emitting elements of the plurality of second light-emitting elements are electrically connected by a conductor not in direct contact with the wiring pattern.

4. The light-emitting device according to claim 3, wherein the second sealant seals the conductor.

5. The light-emitting device according to claim 4, wherein the second sealant that seals the conductor is formed continuously as a whole.

6. The light-emitting device according to claim 5, wherein the second sealant has a lower concentration of phosphor than a concentration of phosphor of the first sealant.

7. The light-emitting device according to claim 1, wherein:
the substrate is a polygonal,
the first light emitter and the second light emitter are alternately arranged along each side of the substrate, and
a same one of the first light emitter and the second light emitter is disposed adjacent every corner of the substrate.

8. The light-emitting device according to claim 1, wherein:
the substrate has an elongated shape, and
the first light emitter and the second light emitter are alternately arranged along at least one long side of the substrate, the long side being included in the periphery of the substrate.

9. An illumination light source including the light-emitting device according to claim 1.

10. A light-emitting device, comprising:
a substrate;
a first light emitter that is disposed on the substrate and emits first light having a first color; and
a second light emitter that is disposed on the substrate and emits second light having a second color different from the first color, wherein:
the first light emitter has a first portion and a second portion,
the second light emitter has a first portion and a second portion,
the first portion of the first light emitter and the first portion of the second light emitter are alternately arranged along a first peripheral line of the substrate, and
the second portion of the first light emitter and the second portion of the second light emitter are alternately arranged along a second peripheral line of the substrate located at an inner side of the first peripheral line.

11. The light-emitting device according to claim 10, wherein:
each of the first and second portions of the first light emitter includes a plurality of first light-emitting elements and a first sealant that seals the plurality of first light-emitting elements and emits fluorescent light when illuminated by light from the plurality of first light-emitting elements, and
each of the first and second portions of the second light emitter includes a plurality of second light-emitting elements and a second sealant that seals the plurality of second light-emitting elements and emits fluorescent light when illuminated by light from the plurality of second light-emitting elements.

12. The light-emitting device according to claim 11,
wherein the first light emitter is continuously formed so as to form a ring shape.

13. The light-emitting device according to claim 12,
wherein the first portion and the second portion of the second light emitter are connected by a connecting pattern that passes under the first light emitter.

14. A light-emitting device, comprising:
a substrate;
a first light emitter that is disposed on the substrate and emits first light having a first color; and
a second light emitter that is disposed on the substrate and emits second light having a second color different from the first color, wherein:
the first light emitter has a first portion and a second portion,
the second light emitter has a first portion and a second portion,
the first portion of the first light emitter and the first portion of the second light emitter are alternately arranged along a first line, and
the second portion of the first light emitter and the second portion of the second light emitter are alternately arranged along a second line parallel with the first line.

15. The light-emitting device according to claim 14, wherein:
each of the first and second portions of the first light emitter includes a plurality of first light-emitting elements and a first sealant that seals the plurality of first light-emitting elements and emits fluorescent light when illuminated by light from the plurality of first light-emitting elements, and
each of the first and second portions of the second light emitter includes a plurality of second light-emitting elements and a second sealant that seals the plurality of second light-emitting elements and emits fluorescent light when illuminated by light from the plurality of second light-emitting elements.

16. The light-emitting device according to claim 14,
wherein the first line and the second line form a ring shape, respectively.
